(19) United States
(12) Patent Application Publication
(10) Pub. No.: US 2007/0107185 A1
(43) Pub. Date: May 17, 2007

(54) Sputtering target assembly having low conductivity backing plate and method of making same

(75) Inventors: Robert S. Bailey, Grove City, OH (US); Melvin K. Holcomb, Grove City, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: TOSOH SMD, INC., Grove City, OH (US)

(21) Appl. No.: 10/564,173

(22) PCT Filed: Jul. 13, 2004
(86) PCT No.: PCT/US04/22615

§ 371 Date: Jun. 22, 2006

Related U.S. Application Data
(60) Provisional application No. 60/487,094, filed on Jul. 14, 2003.
(60) Provisional application No. 60/527,917, filed on Dec. 8, 2003.

(51) Int. Cl. B21D 39/03; C23C 14/00

(52) U.S. Cl. 29/428; 204/298.12

(57) ABSTRACT

A target and backing plate assembly and method of making the same. The backing plate is made of a material having an electrical conductivity less than or equal to 45% IACS and is selected from the group consisting of Al alloys, Cu alloys, magnesium, magnesium alloys, molybdenum, molybdenum alloys, zinc, zinc alloys, nickel and nickel alloys.

### CROSS-REFERENCE TO RELATED INVENTION

The benefit of prior U.S. Provisional Application No. 60/487,094 filed Jul. 14, 2003 and U.S. Provisional Application No. 60/527,917 filed Dec. 8, 2003, is hereby claimed.

### BACKGROUND OF THE INVENTION

1. Field of Invention

This invention relates to a sputter target/backing plate assembly and more specifically to a sputter target/backing plate assembly having a backing plate made of low conductivity material.

2. Description of Related Art

Physical vapor deposition (PVD), also referred to as sputtering, uses a solid metal, such as titanium, as the source or target to deposit material onto a substrate. During a PVD process, metal atoms are produced by dislodging them from the target with high energy ion bombardment. The high energy ions that cause sputtering are typically from a cloud of plasma in front of the sputtering target. The plasma is typically formed of a heavy inert gas, such as argon. The substrate is provided on a pedestal at a selected distance from the target and held at a negative potential with respect to the plasma generated by a power source. A major portion of the sputtered metal atoms or groups of atoms follow a substantially linear trajectory over a distribution of angles due to the low pressure maintained in the chamber.

The plasma is sustained by a magnetic field produced by magnets behind the sputtering target. In a typical sputtering system, there are rotating magnets which help direct the plasma in the system and enable more uniform sputtering of the target to occur. In an advanced magnetron PVD design, the cathode magnet usually consists of an array of small magnets rotating around a target center axis to give better uniformity performance. At different locations on the target surface the magnetic field strength and the average residence time of the magnetic field per revolution of the magnets vary. Both of these variations contribute to the existence of different sputtering rates at different locations on the target surface, hence the existence of the target sputtering profile (sputtering grooves). We define the time integration of the magnetic field strength within a revolution as time averaged magnetic field strength (T-B-Field). In a commercial PVD system, the OEM usually designs the configuration of the cathode magnet assembly to form the desired T-B-Field. This, in turn, creates the desired target surface erosion profile that is adapted to achieve optimal deposition uniformity performance. Methods for determining desired magnet configuration and target erosion profiles may be seen upon review of U.S. Pat. Nos. 4,995,958; 5,314,597; 5,248,402; 5,830,327; and 5,252,194.

The density of the plasma and, hence, the rate of sputtering of the target is related to the magnetic field strength at the target surface. Electrical-magnetic theory indicates that the maximum sputtering rate occurs when the vertical component of the magnetic field is zero and the horizontal component of the magnetic field is at maximum. In the following, the term “magnetic field” refers to the horizontal component of the magnetic field when the vertical magnetic field is near zero if it is not otherwise indicated. If the magnetic field strength is at too low a level, the plasma will be extinguished, and no sputtering of the target material will occur.

A sputtering target assembly typically comprises a backing plate bonded to the target for providing structural support to the assembly. Typically, backing plate materials have been chosen for strength, corrosion resistance and heat transfer characteristics. Strength is needed to provide a structure that can withstand the stress during operation in a sputtering system and to reduce particle generation by reducing bowing during sputtering operations. Corrosion and heat transfer characteristics have been important to allow the assembly to dissipate heat during sputtering. The targets typically get extremely hot and are water-cooled on the backing plate side, hence the need for corrosion resistance and heat dissipation.

Typically, a precipitation hardened material, such as Al 6061 or CuCr (C18200), having a high thermal conductivity has been used for the backing plate. The high thermal conductivity materials typically chosen for their cooling efficiency also have high electrical conductivity. For example, the CuCr alloy has high electrical conductivity between about 80-85% IACS and the Al 6061 has an electrical conductivity of about 46% IACS. Such high conductivity backing plates lead to reduced magnetic field penetration through the target assembly due to eddy currents formed in the backing plate induced by the rotation of magnet. This reduced magnetic field results in lower plasma density and corresponding reduced sputtering deposition rates.

Accordingly, a need exists for a target and backing plate assembly that permits a higher magnetic field penetration so as to enable quicker process times to deposit the desired thickness of film during sputtering, thereby resulting in more efficient and economical sputtering.

### SUMMARY OF THE INVENTION

This invention provides a sputtering target assembly comprising a target and a backing plate wherein the backing plate is made of a material having a conductivity less than or equal to 45% IACS. The backing plate material is preferably selected from the group consisting of Al alloys, Cu alloys, magnesium, magnesium alloys, molybdenum, molybdenum alloys, zinc, zinc alloys, nickel and nickel alloys. In another embodiment, the conductivity of the backing plate material is less than 35% IACS.

In one embodiment, the backing plate material is brass having a composition of greater than 20% Zn. In a further embodiment, the backing plate material is bronze, wherein the composition of the backing plate is less than 1.25 weight percent Sn. In yet another embodiment, the backing plate material is an aluminum alloy, such as a 5000 series Al with a composition greater than 2 weight percent Mg. In a further embodiment, the backing plate material is a CuZn alloy. Each of these materials have a conductivity less than 45% IACS, so that eddy current formation in the backing plate is minimized.

The invention is also directed toward a sputtering target assembly comprising a target and a backing plate wherein the backing plate is made of a material having an electrical conductivity less than or equal to 35% IACS.

The invention also is directed toward a method of forming a sputtering target assembly. The method includes the steps of forming a backing plate from a material having a conductivity less than 45% IACS, and bonding the backing plate to a sputter target. In another embodiment, the backing plate material is selected from the group consisting of Al alloys, Cu alloys, magnesium, magnesium alloys, molybdenum, molybdenum alloys, zinc, zinc alloys, nickel and nickel alloys.

These and other features and advantages of this invention are described in, or are apparent from, the following detailed description of various exemplary embodiments of the systems and methods according to this invention.

### BRIEF DESCRIPTION OF THE DRAWINGS

Various exemplary embodiments of the systems and methods of this invention will be described in detail with reference to the following figures, wherein:

FIG. 1 illustrates one exemplary embodiment of a target and backing plate in accordance with the invention.

Corresponding reference characters indicate corresponding parts throughout the views of the drawings.

### DETAILED DESCRIPTION OF EXEMPLARY EMBODIMENTS

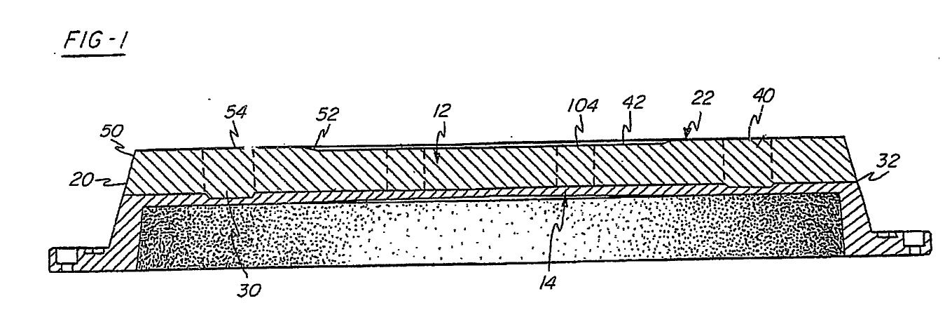

FIG. 1 shows a partially schematic perspective view of a sputtering target assembly, indicated generally at 10, in accordance with the inventive concepts herein disclosed. The sputtering target assembly 10 includes a sputter target 12, superposed atop a backing plate 14. The target 12 may be composed for example of a metallic material such as Ti, Ni, Ti/W, W, Co, Al and/or Ta or alloys thereof. Desirably, the target 12 is in the shape of an annulus, initially (i.e. before sputtering occurs) having a planar sputtering surface 22 which will provide the requisite metal surface that will be consumed during sputtering operations to form the desired coating on a substrate. The method of determining the target thickness can be according to commonly assigned U.S. application Ser. No. 10/312,050 entitled “Target and Method of Optimizing Target Profile” filed Feb. 20, 2002, which is hereby fully incorporated by reference.

The sputtering target assembly 10 is used in a conventional sputtering system (not shown). The sputtering system includes an anode connected to ground potential and cathode, i.e., the target 12, connected to a negative high voltage source. In typical sputtering systems, a plasma shield is electrically grounded and serves as the anode. The substrate or wafer to be coated (not shown) is held by a suitable wafer holding means so that the surface of the wafer is exposed to and parallel to the planar surface 22 of target 12. An inert gas at low pressure, for example Argon at 5 millitorr, is introduced into the sputtering device. Typically, the sputtering system has a rotating magnet which helps direct the plasma in the system and allow more uniform sputtering of the target to occur. For example, the sputtering system may have an array of small magnets rotating around a target center axis to give better uniformity performance. Sputtering devices are well known in the art and will not be further described herein.

Target 12 is bonded to the backing plate 14 using a method such as disclosed in commonly assigned U.S. patent application Ser. No. 10/700,309 filed Oct. 31, 2003, entitled “Diffusion bonded Sputter Target Assembly and Method of Making Same”, or U.S. Pat. No. 6,749,103, filed Dec. 21, 2000, entitled “Low Temperature Sputter Target Bonding Method and Target Assemblies Produced Thereby”, the disclosures of which are hereby incorporated by reference. Other methods for bonding the target 12 and backing plate 14, including soldering, brazing, friction welding, explosion bonding or mechanical bonding, are likewise contemplated. Good quality thermal and structural bonding of the target 12 and backing plate 14 is desired to ensure sufficient cooling of the sputter target assembly 10 after bonding and to maintain the structural integrity of the assembly during high temperature conditions.

The preferred target 12 is generally frusto-conical in shape, being circular in plan and possessing side walls 20 which converge in a generally linear fashion in the direction of a sputtering surface 22. In cross-section, the preferred target 12 and backing plate 14 have the overall configuration of a frustum, with the backing plate 14 serving as the base of the cone and the target side walls 20 serving as the mid-position of the cone, such that the side walls 20 would approach an apex of the cone if the side walls 20 were extended beyond the sputtering surface 22.

In one suitable embodiment, a thickened area or circular boss 30 is formed along the target/backing plate interface 32. This thickened area 30 serves to increase target life by acting as an erosion track extension or the like. In the embodiment illustrated, the radial dimension of this thickened area 30 is preferably about 3.047 inch (about 7.739 cm) and the depth is preferably about 0.050 inch (about 1.3 mm).

The sputtering surface 22 suitably includes an outer, stepped-up or elevated terrace area 40 of increased target thickness surrounding a shallow well 42 defining a thinner, central region of the target 12. The terrace 40 comprises an outer wall 50 and an inner wall 52. The inner wall 52 slopes outwardly from the well toward a plateau or outer surface 54 of the terrace at an angle of about 13.5° in the particular embodiment that is depicted. The inner wall 52 has a length or radial dimension of about 0.25 inch (about 6.4 mm). As shown, the surface of the terrace 40 is raised about 0.060 inch from the surface of the well. The terrace 40 provides additional material thickness in a region of the sputtering surface 22 where high erosion can be anticipated.

In operation, the magnetic field lines confine the discharge to an annular region, where energetic ions in the discharge bombard and erode target 12 by dislodging atoms, some of which coat the planar surface of the wafer (not shown). It is a concern that eddy currents in the target 12 and the backing plate 14 due to the motion of the magnet of the sputtering system will degrade the magnetic field and adversely effect the sputtering operation. The eddy current reduces the strength of the magnetic field above the target surface 22. The high thermal conductivity materials previously chosen for their cooling efficiency also have high electrical conductivity. High conductive materials lead to the formation of higher eddy currents. As can be understood, the higher the eddy current effects in the backing plate 14, the less magnetic field penetrates the sputtering assembly. Thus, forming the backing plate 14 from a high conductivity material reduces the magnetic field above the target 12. Reduced thermal conductivity can be tolerated, in favor of lower electrical conductivity materials. Using a backing plate 14 made from low conductivity material reduces the eddy current effect and enables a higher magnetic field to penetrate through the sputtering assembly 10. This higher magnetic field penetrating the sputtering assembly 10 results in a more stable plasma. One advantage of the higher magnetic field is increased sputter rates.

According to the invention, the backing plate is composed of a low conductivity material having a conductivity of less than or equal to about 45% IACS (International Annealed Copper Standard), suitably less than 40% IACS, and more preferably less than 35% IACS. Preferably, the backing plate 14 is composed of a material having a conductivity greater than a minimum conductivity of about 10% IACS so that the conductivity is not too low so as to unacceptably degrade the cooling capacity of the backing plate. Examples of acceptable backing plate material include: Al alloys, Cu alloys such as brass and bronze, magnesium and magnesium alloys, molybdenum and molybdenum alloys, zinc and zinc alloys, nickel and nickel alloys, wherein the backing plate material has a conductivity less than or equal to 45% IACS.

In one embodiment, the backing plate material is an aluminum alloy selected from a 2000 series, 5000 series or 7000 series aluminum alloy. In one preferred embodiment, the backing plate material is a 5000 series alloy with a composition having greater than 2 weight percent Mg. Examples of suitable 5000 series alloys are 5052, 5056, 5083, 5086, 5154, 5252, 5254, 5356, 5454 and 5456. Examples of other suitable Al alloys are 7075 and 7198, 2014, 2017, 2024 and 2219. Examples of selected suitable Al alloys and their conductivities are shown in Table 1.

TABLE 1

| Alloy | Composition | Conductivity |
|---|---|---|
| 5083 (0 temper) | 94.75% Al | 29% IACS |
| | .7% Mn | |
| | 4.4% Mg | |
| | .15% Cr | |
| 7075 (T6 temper) | 90.07% Al | 33% IACS |
| | 1.6% Cu | |
| | 2.5% Mg | |
| | .23% Cr | |
| | 5.6% Zn | |
| 2024 | 93.5% Al | 30% IACS |
| (T3, T4, T361 | 4.4% Cu | |
| temper) | .6% Mn | |
| | 1.5% Mg | |

Another suitable backing plate material is brass, wherein the composition of the backing plate is greater than or equal to about 20 weight percent Zn. Examples of suitable brass alloys and conductivities are shown in Table 2.

TABLE 2

| Alloy | Composition | Conductivity |
|---|---|---|
| C24000 | 80% Cu | 32% IACS |
| | 20% Zn | |
| C46400 | 60.8% Cu | 26% IACS |
| | 39.2% Zn | |

Another suitable example is a backing plate 14 made of bronze. Preferably, the composition of the backing plate is less than about 5.0 percent Sn and more preferably less than about 1.25 weight percent Sn. Examples of suitable bronze alloys and conductivities are shown in Table 3.

TABLE 3

| Alloy | Composition | Conductivity |
|---|---|---|
| C51100 | 95.6% Cu | 20% IACS |
| | .2% P | |
| | 4.2% Sn | |

Without being bound by any particular theory, the reduction in the eddy current effect is believed to enable a higher magnetic field to penetrate through the backing plate 14. The higher magnetic field penetrating the sputtering assembly 10 results in a more stable plasma, thereby increasing sputter rates. Additionally the more stable plasma enables operation at lower pressure. One recognized advantage is the thickness of the target 12 may be increased with similar sputtering performance with longer life.

### EXAMPLE 1

A conventional 200 mm sputtering target assembly having a Ta target and CuCr (C18000) backing plate widely used in the industry was obtained. A new 200 mm sputtering target assembly having a Ta target with a low conductivity backing plate was designed according to the present invention. The backing plate was made of a CuZn alloy (C46400) which has a conductivity of 26% IACS at 68 F. By comparison, the CuCr has a conductivity of 80% IACS at 68 F. The difference in conductivity was found to result in less drag on the rotating magnet in the sputtering system due to a reduction in eddy current in the backing plate. This reduced eddy current allowed more of the magnetic strength to pass through the target resulting in a 15% increase in sputter rate of the target.

While this invention has been described in conjunction with the specific embodiments above, it is evident that many alternatives, combinations, modifications, and variations are apparent to those skilled in the art. Accordingly, the preferred embodiments of this invention, as set forth above, are intended to be illustrative, and not limiting. Various changes can be made without departing from the spirit and scope of this invention.

What is claimed is:

1. A sputtering target assembly comprising a target and a backing plate wherein the backing plate is made of a material having a conductivity less than or equal to 45% IACS and wherein the material is selected from the group consisting of: Al alloys, Cu alloys, magnesium, magnesium alloys, molybdenum, molybdenum alloys, zinc, zinc alloys, nickel and nickel alloys.

2. The assembly as recited in claim 1 wherein said conductivity of the backing plate material is less than 35% IACS.

3. The assembly as recited in claim 1 wherein the backing plate material is brass having a composition of at least 20% Zn.

4. The assembly as recited in claim 1 wherein the backing plate material is bronze, wherein the composition of the backing plate is less than 1.25 weight percent Sn.

5. The assembly as recited in claim 1 wherein the backing plate material is an aluminum alloy, wherein the alloy is a 5000 series Al with a composition greater than 2 weight percent Mg.

6. The assembly as recited in claim 1 wherein the backing plate material is a 5000 series aluminum alloy selected from the group consisting of: 5052, 5056, 5083, 5086, 5154, 5252, 5254, 5356, 5454 and 5456.

7. The assembly as recited in claim 1 wherein the backing plate material is a 7000 series aluminum alloy selected from the group consisting of: 7075 and 7198.

8. The assembly as recited in claim 1 wherein the backing plate material is a 2000 series aluminum alloy selected from the group consisting of: 2014, 2017, 2024 and 2219.

9. The assembly as recited in claim 1 wherein the conductivity of the backing plate material is between 10% and 45% IACS.

10. A sputtering target assembly comprising a target and a backing plate wherein the backing plate is made of a material having an electrical conductivity less than or equal to 35% IACS.

11. A method of forming a sputtering target assembly comprising the steps of:
forming a backing plate from a material having a conductivity less than 45% IACS;
bonding the backing plate to a sputter target.

12. The method of claim 11 wherein the backing plate material is selected from the group consisting of Al alloys, Cu alloys, magnesium, magnesium alloys, molybdenum, molybdenum alloys, zinc, zinc alloys, nickel and nickel alloys.
